(19) United States
(12) Patent Application Publication
(10) Pub. No.: US 2025/0144766 A1
(43) Pub. Date: May 8, 2025

(54) POLISHING PAD AND METHOD OF MANUFACTURING A SEMICONDUCTOR DEVICE USING THE SAME

(71) Applicant: SK enpulse Co., Ltd., Gyeonggi-do (KR)

(72) Inventors: Yujin SHIN, Gyeonggi-do (KR); Joonho AN, Gyeonggi-do (KR); Kyunghwan KIM, Gyeonggi-do (KR); Jangwon SEO, Gyeonggi-do (KR)

(21) Appl. No.: 18/882,756

(22) Filed: Sep. 12, 2024

(30) Foreign Application Priority Data
Nov. 6, 2023 (KR) 10-2023-0151983

(51) Int. Cl. B24B 37/24; C09G 1/16; H01L 21/3105

(52) U.S. Cl. CPC B24B 37/24; C09G 1/16; H01L 21/31053

(57) ABSTRACT

The polishing pad according to an embodiment can reduce noise and vibration in a specific frequency range. Accordingly, the polishing pad has excellent sound absorption characteristics since the maximum sound absorption coefficient satisfies 0.1 or more as measured at a frequency of 500 Hz to 4,000 Hz according to Equation 1. Thus, since it can minimize energy loss caused by heat energy or vibration energy in a CMP polishing process, it has an excellent polishing rate.

### CROSS-REFERENCE TO RELATED APPLICATIONS

This application claims priority under 35 U.S.C. § 119 to Korean Patent Application No. 10-2023-0151983 filed on Nov. 6, 2023 in the Korean Intellectual Property Office. The entire disclosure of each of the foregoing applications is incorporated herein by reference in its entirety.

### TECHNICAL FIELD

Embodiments relate to a polishing pad for use in a chemical mechanical planarization (CMP) process of semiconductor devices. Specifically, they relate to a polishing pad that has excellent sound absorption characteristics, whereby it can minimize energy loss caused by heat energy and vibration energy during a CMP polishing process, and to a process for preparing the same.

### BACKGROUND ART

The chemical mechanical planarization (CMP) process in a process for preparing semiconductors refers to a step in which a semiconductor substrate such as a wafer is fixed to a head and in contact with the surface of a polishing pad mounted on a platen, and the platen and the head are relatively moved to planarize the irregularities on the surface of the semiconductor substrate.

In such a CMP process, the polishing pad is required to have stable physical properties because it greatly affects the surface processing quality of the semiconductor substrate. In particular, since the polishing rate of the CMP process may vary sensitively depending on the components contained in the polishing pad and their physical properties, it is necessary to optimize the components contained in the polishing pad and their physical properties.

In addition, polishing is carried out through friction energy in a CMP polishing process. In such an event, energy loss may be caused by heat or vibration generated during the process, and this energy loss may deteriorate performance, such as a decrease in the polishing rate. In the past, in order to reduce energy loss, a method of reducing rigidity by producing a softer polishing pad was adopted. However, the reduced rigidity has the disadvantage that the flatness effect may be reduced. Accordingly, research has been continued on a polishing pad that can minimize energy loss to enhance the polishing rate, without deteriorating the physical properties or processability of the polishing pad, and a process for preparing the same.

### PRIOR ART DOCUMENT

(Patent Document 1) Korean Laid-open Patent Publication No. 2016-0027075

### DISCLOSURE OF INVENTION

### Technical Problem

Accordingly, the embodiments aim to provide a polishing pad that has an excellent polishing rate since it has excellent sound absorption characteristics, whereby it can minimize energy loss caused by heat energy and vibration energy during a CMP polishing process, without deteriorating the physical properties or processability of the polishing pad, and a process for preparing a semiconductor device using the same.

### Solution to Problem

The polishing pad according to an embodiment comprises a polishing layer, wherein the polishing layer comprises a urethane-based prepolymer, a foaming agent, and a curing agent, and the maximum sound absorption coefficient is 0.1 or more as measured at a frequency of 500 Hz to 4,000 Hz according to the following Equation 1.

$$Sound absorption coefficient = ( {I}_{i} - {I}_{r} ) / {I}_{i} = ( {I}_{a} + {I}_{t} ) / {I}_{i} \qquad [ Equation 1 ]$$

In Equation 1, when the polishing pad is cut (diameter: 45 mm) to measure sound pressure within an impedance tube according to KS F 2814-2, Iᵢ is the intensity of the incident sound, Iᵣ is the intensity of the reflected sound, Iₐ is the intensity of the absorbed sound, and Iₜ is the intensity of the transmitted sound.

The process for preparing a semiconductor device according to another embodiment comprises polishing the surface of a semiconductor substrate using the polishing pad.

### Advantageous Effects of Invention

The polishing pad according to an embodiment can reduce noise and vibration in a specific frequency range. Specifically, the polishing pad has excellent sound absorption characteristics since the maximum sound absorption coefficient satisfies 0.1 or more as measured at a frequency of 500 Hz to 4,000 Hz according to Equation 1. Thus, since it can minimize energy loss caused by heat energy or vibration energy in a CMP polishing process, it has an excellent polishing rate.

More specifically, the polishing pad comprises a urethane-based prepolymer, a foaming agent, and a curing agent, and the types and contents of the foaming agent and curing agent are adjusted. Thus, it can reduce noise and vibration in a specific frequency range to minimize energy loss caused by vibration energy; thus, it can maximize the efficiency of friction energy to enhance the polishing rate.

In addition, since the polishing pad according to the embodiment can enhance the polishing rate by minimizing energy loss, without deteriorating the physical properties and processability of the polishing pad, it is possible to enhance CMP performance and yield when a semiconductor device is fabricated using the same.

### BRIEF DESCRIPTION OF DRAWINGS

FIG. 1 shows the results of Test Example 1, in which the sound absorption coefficient of the polishing pads of Examples 1 to 3 and Comparative Examples 1 and 2 was measured according to KS F 2814-2.

FIG. 2 schematically illustrates a process for preparing a semiconductor device according to an embodiment.

### REFERENCE NUMERAL OF THE DRAWINGS

100: polishing pad, 200: platen, 300: conditioner, 400: polishing slurry, 510: polishing head, 520: carrier, 600: semiconductor substrate (wafer)

### BEST MODE FOR CARRYING OUT THE INVENTION

Hereinafter, the present invention will be described in detail with reference to embodiments. The embodiments are not limited to what has been disclosed below. The embodiments may be modified into various forms as long as the gist of the invention is not altered.

In this specification, terms referring to the respective components are used to distinguish them from each other and are not intended to limit the scope of the embodiment. In addition, in the present specification, a singular expression is interpreted to cover a plural number as well unless otherwise specified in the context.

Throughout the present specification, when a part is referred to as “comprising” an element, it is understood that other elements may be comprised, rather than other elements are excluded, unless specifically stated otherwise.

In the present specification, when one component is described to be formed on/under another component or connected or coupled to each other, it covers the cases where these components are directly or indirectly formed, connected, or coupled through another component. In addition, it should be understood that the criterion for the terms on and under of each component may vary depending on the direction in which the object is observed.

All numerical ranges related to the physical properties, dimensions, and the like of a component used herein are to be understood as being modified by the term “about,” unless otherwise indicated.

In the numerical range that limits the size, physical properties, and the like of components described in the present specification, when a numerical range limited with the upper limit only and a numerical range limited with the lower limit only are separately exemplified, it should be understood that a numerical range combining these upper and lower limits is also encompassed in the exemplary scope of the invention.

### Polishing Pad

The polishing pad according to an embodiment comprises a polishing layer, wherein the polishing layer comprises a urethane-based prepolymer, a foaming agent, and a curing agent, and the maximum sound absorption coefficient is 0.1 or more as measured at a frequency of 500 Hz to 4,000 Hz according to the following Equation 1.

$$Sound absorption coefficient = ( {I}_{i} - {I}_{r} ) / {I}_{i} = ( {I}_{a} + {I}_{t} ) / {I}_{i} \qquad [ Equation 1 ]$$

In Equation 1, when the polishing pad is cut (diameter: 45 mm) to measure sound pressure within an impedance tube according to KS F 2814-2, Iᵢ is the intensity of the incident sound, Iᵣ is the intensity of the reflected sound, Iₐ is the intensity of the absorbed sound, and Iₜ is the intensity of the transmitted sound.

According to an embodiment of the present invention, the maximum sound absorption coefficient of the polishing pad is 0.1 or more as measured at a frequency of 500 Hz to 4,000 Hz according to the above Equation 1.

Specifically, according to KS F 2814-2, the polishing pad is cut, the specimen is placed within an impedance tube, and a plane wave sound source is generated within the tube to measure sound pressure. In such an event, the running frequency range is 500 Hz to 4,000 Hz. The measured sound pressure is used to calculate the sound absorption coefficient according to the above Equation 1.

For example, the maximum sound absorption coefficient of the polishing pad may be 0.11 or more, 0.12 or more, 0.15 or more, 0.16 or more, 0.18 or more, or 0.2 or more, as measured at 500 Hz to 4,000 Hz, 750 Hz 3,500 Hz, 1,000 Hz to 3,200 Hz, 1,500 Hz to 3,000 Hz, 1,500 Hz to 2,500 Hz, 1,600 Hz to 2,500 Hz, or 1,700 Hz to 2,300 Hz, according to KS F 2814-2.

In addition, the maximum sound absorption coefficient of the polishing pad may be 0.05 or more as measured at a frequency of 500 Hz to 1,500 Hz according to KS F 2814-2. For example, the maximum sound absorption coefficient of the polishing pad may be 0.06 or more, 0.07 or more, or 0.08 or more, as measured at 700 Hz to 1,500 Hz, 800 Hz to 1,500 Hz, 900 Hz to 1,500 Hz, or 1,000 Hz to 1,500 Hz, according to KS F 2814-2.

According to an embodiment, the maximum sound absorption coefficient is 0.05 or more as measured at a frequency of 1,000 Hz to 1,500 Hz, and the maximum sound absorption coefficient is 0.1 or more as measured at a frequency of 1,500 Hz to 3,000 Hz.

According to an embodiment, when a sound absorption coefficient is measured at 500 Hz to 4,000 Hz according to KS F 2814-2, the polishing pad may have a sound absorption peak A of 0.05 or more at 500 Hz to 1,500 Hz and a sound absorption peak B of 0.1 or more at 1,600 Hz to 2,500 Hz.

As the polishing pad according to an embodiment has a maximum sound absorption coefficient that satisfies the above range, it can reduce noise and vibration in a specific frequency range to minimize energy loss caused by vibration energy; thus, it can maximize the efficiency of friction energy, resulting in an excellent polishing rate.

According to an embodiment, when the silicon oxide layer of a silicon wafer is polished with a ceria slurry using the polishing pad, the polishing rate (removal rate) according to the following Mathematical Equation 1 may be 2,150 Å/minute to 3,500 Å/minute, 2,150 Å/minute to 3,400 Å/minute, or 2,200 Å/minute to 3,200 Å/minute.

$$Polishing rate ( Å / minute ) = \qquad [ Mathematical Equation 1 ]$$

$$difference in thickness before and after polishing ( Å ) /$$

$$polishing time ( minute )$$

In addition, when the silicon oxide layer of a silicon wafer is polished with a silica slurry using the polishing pad, the polishing rate according to the above Mathematical Equation 1 may be 3,500 Å/minute to 4,500 Å/minute, 3,600 Å/minute to 4,300 Å/minute, or 3,850 Å/minute to 4,200 Å/minute.

### Polishing Layer

The polishing pad according to an embodiment comprises a polishing layer. Specifically, the polishing pad comprises a polishing layer comprising a polyurethane resin.

The polishing layer comprises a urethane-based prepolymer, a foaming agent, and a curing agent. Specifically, the polyurethane resin may be formed from a composition that comprises a urethane-based prepolymer, a foaming agent, and a curing agent.

More specifically, the polishing layer comprises a polyurethane-based resin, which is a reaction product of a urethane-based prepolymer, a foaming agent, and a curing agent, i.e., a cured product of a composition in which the components are mixed. As a result, it comprises a porous polyurethane-based resin. In addition, the polishing layer may comprise a plurality of pores formed from the foaming agent.

The polishing layer may have a thickness of, for example, 0.8 mm or more, 1 mm or more, 1.2 mm or more, or 1.5 mm or more, and 5 mm or less, 3 mm or less, 2.5 mm or less, or 2 mm or less. As a specific example, the thickness of the polishing layer may be 0.8 mm to 5 mm or 1.5 mm to 3 mm.

The polishing layer may have a specific gravity of, for example, 0.6 g/cm³ or more, 0.7 g/cm³ or more, or 0.75 g/cm³ or more, and 0.9 g/cm³ or less, 0.85 g/cm³ or less, or 0.8 g/cm³ or less. As a specific example, the specific gravity of the polishing layer may be 0.6 g/cm³ to 0.9 g/cm³ or 0.7 g/cm³ to 0.9 g/cm³.

The polishing layer may have a hardness of, for example, 30 Shore D or more, 40 Shore D or more, or 50 Shore D or more, and 80 Shore D or less, 70 Shore D or less, 65 Shore D or less, or 60 Shore D or less. As a specific example, the hardness of the polishing layer may be 30 Shore D to 80 Shore D or 50 Shore D to 65 Shore D.

The polishing layer may have a tensile strength of, for example, 5 N/mm² or more, 10 N/mm² or more, or 15 N/mm² or more, and 30 N/mm² or less, 25 N/mm² or less, or 20 N/mm² or less. As a specific example, the tensile strength of the polishing layer may be 5 N/mm² to 30 N/mm² or 15 N/mm² to 25 N/mm².

The polishing layer may have an elongation of, for example, 50% or more, 70% or more, 90% or more, 106% or more, or 120% or more, and 300% or less, 250% or less, 200% or less, or 150% or less. As a specific example, the elongation of the polishing layer may be 50% to 300% or 90% to 130%. The elongation may be an elongation at break.

As a specific example, the polishing layer may have a hardness of 50 Shore D to 65 Shore D, a tensile strength of 15 N/mm² to 25 N/mm², and an elongation of 90% to 130%.

The pores are present as dispersed in the polishing layer.

The average diameter of the pores may be, for example, 10 μm to 60 μm, 10 μm to 50 μm, 20 μm to 50 μm, 20 μm to 40 μm, 10 μm to 30 μm, 20 μm to 25 μm, or 30 μm to 50 μm.

In addition, the total area of the pores may be 30% to 60%, 35% to 50%, or 35% to 43%, based on the total area of the polishing layer. In addition, the total volume of the pores may be 30 to 70%, or 40 to 60%, based on the total volume of the polishing layer.

The polishing layer may have grooves on its surface for mechanical polishing. The grooves may have a depth, a width, and a spacing as desired for mechanical polishing, which is not particularly limited.

The polishing pad according to an embodiment comprises a urethane-based prepolymer.

A prepolymer generally refers to a polymer having a relatively low molecular weight wherein the degree of polymerization is adjusted to an intermediate level for the sake of conveniently molding a product in the process of producing the same. A prepolymer may be molded by itself or after a reaction with another polymerizable compound. For example, a prepolymer may be prepared by reacting an isocyanate compound with a polyol.

The isocyanate compound used in the preparation of the urethane-based prepolymer may be one selected from the group consisting of an aromatic diisocyanate, an aliphatic diisocyanate, an alicyclic diisocyanate, or combinations thereof.

The isocyanate compound may comprise, for example, one selected from the group consisting of toluene 2,4-diisocyanate (2,4-TDI), toluene 2,6-diisocyanate (2,6-TDI), naphthalene 1,5-diisocyanate, para-phenylene diisocyanate, tolidine diisocyanate, 4,4′-diphenylmethane diisocyanate, hexamethylene diisocyanate, dicyclohexylmethane diisocyanate, isophorone diisocyanate, and combinations thereof.

The polyol is a compound comprising at least two or more hydroxyl groups (—OH) per molecule. For example, it may comprise one selected from the group consisting of a polyether polyol, a polyester polyol, a polycarbonate polyol, a polycaprolactone polyol, and combinations thereof.

The polyol may comprise, for example, one selected from the group consisting of polytetramethylene ether glycol, polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol, dipropylene glycol, tripropylene glycol, and combinations thereof.

The polyol may have a weight average molecular weight (Mw) of 100 g/mole to 3,000 g/mole. For example, the weight average molecular weight of the polyol may be 100 g/mole to 3,000 g/mole, 100 g/mole to 2,000 g/mole, or 100 g/mole to 1,800 g/mole.

According to an embodiment, the polyol may comprise a low molecular weight polyol having a weight average molecular weight (Mw) of 100 g/mole to 300 g/mole and a high molecular weight polyol having a weight average molecular weight (Mw) of 300 g/mole to 1,800 g/mole.

In addition, the urethane-based prepolymer may have a weight average molecular weight (Mw) of 500 g/mole to 3,000 g/mole. For example, the weight average molecular weight of the urethane-based prepolymer may be 500 g/mole to 2,500 g/mole, 1,000 g/mole to 2,000 g/mole, or 1,000 g/mole to 1,500 g/mole.

According to an embodiment, the isocyanate compound for the preparation of the urethane-based prepolymer may comprise an aromatic diisocyanate compound, and the aromatic diisocyanate compound, for example, may comprise 2,4-toluene diisocyanate (2,4-TDI) and 2,6-toluene diisocyanate (2,6-TDI). The polyol compound for the preparation of the urethane-based prepolymer may comprise polytetramethylene ether glycol (PTMEG) and diethylene glycol (DEG).

According to an embodiment, the isocyanate compound for the preparation of the urethane-based prepolymer may comprise an aromatic diisocyanate compound and a cycloaliphatic diisocyanate compound. For example, the aromatic diisocyanate compound comprises 2,4-toluene diisocyanate (2,4-TDI) and 2,6-toluene diisocyanate (2,6-TDI), and the cycloaliphatic diisocyanate compound comprises dicyclohexylmethane diisocyanate (H12MDI). The polyol compound for the preparation of the urethane-based prepolymer may comprise polytetramethylene ether glycol (PTMEG) and diethylene glycol (DEG).

The urethane-based prepolymer may have an isocyanate end group content (NCO %) of 5% by weight or more, 8% by weight or more, or 10% by weight or more, and 13% by weight or less, 12% by weight or less, or 11% by weight or less. As a specific example, the urethane-based prepolymer may have an isocyanate end group content (NCO %) of 8% by weight to 11% by weight or 9% by weight to 10% by weight.

The isocyanate end group content (NCO %) of the urethane-based prepolymer may be designed by comprehensively adjusting the type and content of the isocyanate compound and the polyol compound for the preparation of the urethane-based prepolymer, the process conditions such as temperature, pressure, and time in the process for preparing the urethane-based prepolymer, and the type and content of the additives used in the preparation of the urethane-based prepolymer.

If the isocyanate end group content (NCO %) of the urethane-based prepolymer satisfies the above range, the reaction rate, reaction time, and final curing structure in the subsequent reaction between the urethane-based prepolymer and a curing agent can be adjusted in a way favorable to the polishing performance from the viewpoint of the use and purpose of a final polishing pad.

According to an embodiment, the urethane-based prepolymer may have an isocyanate end group content (NCO %) of 8% by weight to 11% by weight or 9% by weight to 10% by weight.

If the NCO % of the urethane-based prepolymer is less than the above range, the electrical properties based on the chemically hardened structure in the polishing pad may be achieved such that the desired polishing performance in terms of polishing rate and flatness are not achieved, and there may be a problem in that the lifespan of the polishing pad is reduced due to an excessive increase in the pad cut rate. On the other hand, if the NCO % exceeds the above range, surface defects such as scratches and chatter marks on a semiconductor substrate may increase.

The foaming agent is a component for forming a pore structure in the polishing layer. It may comprise one selected from the group consisting of a solid phase foaming agent, a gas phase foaming agent, a liquid phase foaming agent, and combinations thereof.

According to an embodiment, the foaming agent may be a non-chlorine-based foaming agent that does not contain a chlorine component. In particular, it may not contain, or minimize the use of, a chlorine-based foaming agent component commonly used in the preparation of polishing pads, such as vinylidene chloride (VDC). For example, the content of the non-chlorine-based foaming agent may be 50% by weight or more, 80% by weight or more, 90% by weight or more, 95% by weight or more, 97% by weight or more, 99% by weight or more, or 99.5% by weight or more, and 100% by weight or less or 99.5% by weight or less, as a specific example, 80% by weight to 100% by weight, 90% by weight to 100% by weight, or 80% by weight to 99.5% by weight, based on the total weight of the foaming agent. In addition, the content of the chlorine-based foaming agent may be 20% by weight or less, 10% by weight or less, 5% by weight or less, 1% by weight or less, 0.5% by weight or less, or 0.3% by weight or less, and 0% by weight or more, 0.1% by weight or more, 0.5% by weight or more, as a specific example, 0% by weight to 20% by weight, 0% by weight to 1% by weight, 0% by weight to 0.5% by weight, or 0.5% by weight to 20% by weight, based on the total weight of the foaming agent.

The foaming agent may comprise at least one selected from a solid phase foaming agent comprising particles having a hollow structure, a liquid phase foaming agent using a volatile liquid, and an inert gas.

As an example, the solid phase foaming agent may comprise particles having a hollow structure that have been expanded by heat and adjusted in size. Such a solid phase foaming agent has the advantage of controlling the size of pores to be uniform as it is employed in the raw material in an already expanded form and has a uniform particle size.

In addition, the solid phase foaming agent may comprise expandable particles. The expandable particles are particles having a characteristic that can be expanded by heat or pressure. Their size in the final polishing layer may be determined by heat or pressure applied in the process of preparing the polishing layer. The expandable particles are employed in the raw material in a particle state that has not been expanded in advance. Their final size is determined when expanded by heat or pressure applied during the process of preparing the polishing layer.

The solid phase foaming agent may have an average particle size of 5 μm to 100 μm, for example, 5 μm to 50 μm, 20 μm to 50 μm, 30 μm to 48 μm, or 35 μm to 45 μm. The average particle size of the solid phase foaming agent may refer to the average particle size of expanded particles themselves when the solid phase foaming agent is particles employed in the raw material in an expanded state as described below. It may refer to the average particle diameter of particles after they are expanded by heat or pressure in the preparation process when the solid phase foaming agent is particles employed in the raw material in an unexpanded state as described below.

The solid phase foaming agent in the form of expandable particles may comprise a shell of a resin; and an expansion-inducing component encapsulated inside the shell. These expandable particles may be formed into a hollow structure by the vaporization of the encapsulated expansion-inducing component by heat during the preparation process.

For example, the shell may comprise a thermoplastic resin. The thermoplastic resin may be at least one selected from the group consisting of an acrylonitrile-based copolymer, a methacrylonitrile-based copolymer, and an acrylic copolymer.

The thickness of the shell may be, for example, 0.1 μm or more, 0.5 μm or more, 1 μm or more, 2 μm or more, or 3 μm or more, and 15 μm or less, 12 μm or less, or 10 μm or less, as a specific example, 2 μm to 15 μm.

The expansion-inducing component may comprise one selected from the group consisting of a hydrocarbon compound, a tetraalkylsilane compound, and combinations thereof. Specifically, the hydrocarbon may comprise one selected from the group consisting of ethane, ethylene, propane, propene, n-butane, isobutane, n-butene, isobutene, n-pentane, isopentane, neopentane, n-hexane, heptane, petroleum ether, and combinations thereof. The tetraalkylsilane compound may comprise one selected from the group consisting of tetramethylsilane, trimethylethylsilane, trimethylisopropylsilane, trimethyl-n-propylsilane, and combinations thereof.

The solid phase foaming agent may comprise particles treated with an inorganic component. In an embodiment, the solid phase foaming agent may be one treated with silica (SiO₂) particles. The treatment of the solid phase foaming agent with an inorganic component can prevent aggregation between a plurality of particles. The solid phase foaming agent treated with an inorganic component may be different from the solid phase foaming agent that is not treated with an inorganic component in terms of the chemical, electrical, and/or physical properties of the surface of the foaming agent.

As a specific example, the foaming agent used in the polishing pad according to an embodiment comprises a solid phase foaming agent. The solid phase foaming agent may comprise at least one selected from the group consisting of an acrylonitrile-based copolymer, a methylmethacrylate-based copolymer, a methacrylonitrile-based copolymer, and an acrylic-based copolymer.

The content of the solid phase foaming agent may be 0.1 part by weight or more, 0.5 part by weight or more, or 1 part by weight or more, and 5 parts by weight or less, 3 parts by weight or less, or 2 parts by weight or less, relative to 100 parts by weight of the urethane-based prepolymer. As a specific example, the content of the solid phase foaming agent may be 0.1 part by weight to 5 parts by weight or 0.5 part by weight to 2 parts by weight, relative to 100 parts by weight of the urethane-based prepolymer.

The type and content of the solid phase foaming agent may be designed according to the desired pore structure and physical properties of the polishing layer.

Meanwhile, the liquid phase foaming agent may be introduced during the mixing and reaction of the prepolymer and the curing agent to form pores. It does not participate in the reaction between the prepolymer and the curing agent. In addition, the liquid phase foaming agent is physically vaporized by heat generated during the mixing and reaction of the prepolymer and the curing agents to form pores.

The volatile liquid phase foaming agent may be liquid at 25° C. while it does not react with an isocyanate group, an amide group, and an alcohol group. Specifically, the volatile liquid phase foaming agent may be selected from the group consisting of cyclopentane, n-pentane, cyclohexane, n-butyl acetate, bis(nonafluorobutyl)(trifluoromethyl)amine; and perfluoro compounds such as perfluorotributylamine, perfluoro-N-methylmorpholine, perfluorotripentylamine, and perfluorohexane. Commercially available products of the perfluoro compound include FC-40 (3M), FC-43 (3M), FC-70 (3M), FC-72 (3M), FC-770 (3M), FC-3283 (3M), and FC-3284 (3M).

In addition, the foaming agent may comprise a gas phase foaming agent. For example, the foaming agent may comprise a solid phase foaming agent and a gas phase foaming agent.

The gas phase foaming agent may comprise an inert gas. The gas phase foaming agent is fed while the urethane-based prepolymer and the curing agent are reacted in order to be used as a component to form pores.

The kind of the inert gas is not particularly limited as long as it is a gas that does not participate in the reaction between the urethane-based prepolymer and the curing agent. For example, the inert gas may comprise one selected from the group consisting of nitrogen gas (N₂), carbon dioxide gas (CO₂), argon gas (Ar), helium gas (He), and combinations thereof.

The type and content of the gas phase foaming agent may be designed according to the desired pore structure and physical properties of the polishing layer.

The inert gas may be fed in a volume of 10% to 30% based on the total volume of the composition. Specifically, the inert gas may be fed in a volume of 15% to 30% based on the total volume of the composition. Specifically, the gas phase foaming agent may be fed through a predetermined feeding line while the urethane-based prepolymer, the solid phase foaming agent, and the curing agent are mixed. For example, the feeding rate of the gas phase foaming agent is about 0.8 L/minute to about 2.0 L/minute, about 0.8 L minute to about 1.8 L/minute, about 0.8 L/minute to about 1.7 L/minute, about 1.0 L/minute to about 2.0 L/minute, about 1.0 L/minute to about 1.8 L/minute, or about 1.0 L/minute to about 1.7 L/minute.

The curing agent is a compound for chemically reacting with the urethane-based prepolymer to form a final cured structure in the polishing layer. For example, it may comprise an amine compound or an alcohol compound. Specifically, the curing agent may comprise one selected from the group consisting of an aromatic amine, an aliphatic amine, an aromatic alcohol, an aliphatic alcohol, and combinations thereof.

According to an embodiment, the curing agent may comprise a non-chlorine-based curing agent that does not contain a chlorine component. For example, the content of the non-chlorine-based curing agent may be 50% by weight or more, 80% by weight or more, 90% by weight or more, 95% by weight or more, 97% by weight or more, 99% by weight or more, or 99.5% by weight or more, and 100% by weight or less or 99.5% by weight or less, as a specific example, 80% by weight to 100% by weight, 90% by weight to 100% by weight, or 80% by weight to 99.5% by weight, based on the total weight of the curing agent. In addition, the content of the chlorine-based curing agent may be 20% by weight or less, 10% by weight or less, 5% by weight or less, 1% by weight or less, 0.5% by weight or less, or 0.3% by weight or less, and 0% by weight or more, 0.1% by weight or more, 0.5% by weight or more, as a specific example, 0% by weight to 20% by weight, 0% by weight to 1% by weight, 0% by weight to 0.5% by weight, or 0.5% by weight to 20% by weight, based on the total weight of the curing agent.

The curing agent may be at least one selected from a solid phase curing agent and a liquid phase curing agent.

The solid phase curing agent may contain an active hydrogen group. The solid phase curing agent may contain an amine group (—NH₂) as an active hydrogen group.

In addition, the solid phase curing agent may be an ester compound containing two or more benzene rings. Specifically, the solid phase curing agent may comprise two or more of the ester groups in the molecule.

The solid phase curing agent may have a weight average molecular weight of, for example, 150 g/mole to 400 g/mole, 150 g/mole to 350 g/mole, 200 g/mole to 350 g/mole, 250 g/mole to 350 g/mole, or 300 g/mole to 350 g/mole. In addition, the solid phase curing agent may have a melting point (m.p.) of 100° C. to 150° C., 100° C. to 140° C., or 110° C. to 130° C.

In an embodiment, the solid phase curing agent comprises at least one selected from the group consisting of 1,3-propanediol bis(4-aminobenzoate) (PDPAB), 4-(4-aminobenzoyl)oxyphenyl 4-aminobenzoate, 4-(4-aminobenzoyl)oxybutyl 4-aminobenzoate, 4-[4-(4-aminobenzoyl)oxy-3-methylbutoxy]butyl 4-aminobenzoate, and methylene bis-methylanthranilate (MBNA).

The liquid phase curing agent may contain an active hydrogen group. The liquid phase curing agent may contain at least one selected from the group consisting of an amine group (—NH₂), a hydroxyl group (—OH), a carboxylic acid group (—COOH), an epoxy group, and a combination thereof as an active hydrogen group. Specifically, it may contain an amine group (—NH₂).

In addition, the liquid phase curing agent may contain sulfur in the molecule. Specifically, it may contain two or more sulfur elements in the molecule.

The liquid phase curing agent may have a weight average molecular weight of 50 g/mole to 300 g/mole, for example, 100 g/mole to 250 g/mole, for example, 150 g/mole to 250 g/mole, for example, 200 g/mole to 250 g/mole.

In addition, the liquid phase curing agent may be liquid at room temperature. Alternatively, the liquid phase curing agent may have a boiling point (b.p.) of 160° C. to 240° C., specifically 170° C. to 240° C., more specifically 170° C. to 220° C.

Examples of the liquid phase curing agent include at least one selected from the group consisting of 3,5-dimethylthio-2,6-diaminotoluene (DMTDA), 2,6-bis(methylthio)-4-methyl-1,3-benzenediamine, and N,N′-bis(sec-butylamino)diphenylmethane.

In addition, the curing agent may further comprise other curing agents in addition to the liquid phase curing agent and the solid phase curing agent. The additional curing agent may be, for example, at least one of an amine compound and an alcohol compound. Specifically, the additional curing agent may comprise at least one compound selected from the group consisting of an aromatic amine, an aliphatic amine, an aromatic alcohol, and an aliphatic alcohol.

For example, the additional curing agent may be at least one selected from the group consisting of diaminodiphenylmethane, diaminodiphenyl sulphone, m-xylylene diamine, isophoronediamine, ethylenediamine, diethylenetriamine, triethylenetetramine, polypropylenediamine, polypropylenetriamine, ethylene glycol, diethylene glycol, dipropylene glycol, butanediol, hexanediol, glycerin, and trimethylolpropane.

As a specific example, the curing agent may comprise at least one selected from the group consisting of 4,4′-methylenebis(2-chloroaniline) (MOCA), diethyltoluenediamine (DETDA), 3,5-dimethylthio-2,6-diaminotoluene (DMTDA), 1,3-propanediol bis(4-aminobenzoate) (PDPAB), N,N′-bis(sec-butylamino)diphenylmethane, 2,6-bis(methylthio)-4-methyl-1,3-benzenediamine, 4-(4-aminobenzoyl)oxyphenyl 4-aminobenzoate, 4-(4-aminobenzoyl)oxybutyl 4-aminobenzoate, 4-[4-(4-aminobenzoyl)oxy-3-methylbutoxy]butyl 4-aminobenzoate, and methylene bis-methylanthranilate (MBNA).

The content of the curing agent may be 5 parts by weight or more, 10 parts by weight or more, 15 parts by weight or more, or 20 parts by weight or more, and 50 parts by weight or less, 45 parts by weight or less, 40 parts by weight or less, 35 parts by weight or less, 30 parts by weight or less, or 25 parts by weight or less, relative to 100 parts by weight of the urethane-based prepolymer. The content of the curing agent may be 10 parts by weight to 40 parts by weight, more specifically, 15 parts by weight to 35 parts by weight or 15 parts by weight to 25 parts by weight, relative to 100 parts by weight of the urethane-based prepolymer.

In addition, the equivalent ratio of the urethane-based prepolymer and the curing agent may be 1:0.5 to 2. For example, the equivalent ratio of the urethane-based prepolymer and the curing agent may be 1:0.5 to 1.8, 1:0.5 to 1.5, 1:0.5 to 1.0, 1:0.6 to 1.2, 1:0.8 to 1.2, or 1:0.8 to 1.0.

As the equivalent ratio of the urethane-based prepolymer and the curing agent satisfies the above range, it can reduce noise and vibration in a specific frequency range to minimize energy loss caused by vibration energy; thus, it can maximize the efficiency of friction energy to enhance the polishing rate.

The composition for preparing a polishing layer may further comprise other additives such as a surfactant and a reaction rate controlling agent. The names such as “surfactant” and “reaction rate controlling agent” are arbitrary names based on the main role of the substances. The respective substances do not necessarily perform only a function limited to the role defined by the names.

The surfactant is not particularly limited as long as it acts to prevent pores from coalescing and overlapping with each other. For example, the surfactant may comprise a silicone-based surfactant.

The surfactant may be employed in an amount of 0.2 part by weight to 2 parts by weight relative to 100 parts by weight of the urethane-based prepolymer. Specifically, the surfactant may be employed in an amount of 0.2 part by weight to 1.9 parts by weight, 0.2 part by weight to 1.8 parts by weight, 0.2 part by weight to 1.7 parts by weight, 0.2 part by weight to 1.6 parts by weight, 0.2 part by weight to 1.5 parts, or 0.5 part by weight to 1.5 parts by weight, relative to 100 parts by weight of the urethane-based prepolymer. If the amount of the surfactant is within the above range, pores derived from the gas phase foaming agent can be stably formed and maintained in the mold.

The reaction rate controlling agent serves to promote or retard the reaction. A reaction promoter, a reaction retarder, or both may be used depending on the purpose. The reaction rate controlling agent may comprise a reaction promoter. For example, the reaction rate controlling agent may be at least one reaction promoter selected from the group consisting of a tertiary amine-based compound and an organometallic compound.

Specifically, the reaction rate controlling agent may comprise at least one selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl) ether, trimethylaminoethylethanolamine, N,N,N,N,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanorbornane, dibutyltin dilaurate, stannous octoate, dibutyltin diacetate, dioctyltin diacetate, dibutyltin maleate, dibutyltin di-2-ethylhexanoate, and dibutyltin dimercaptide. Specifically, the reaction rate controlling agent may comprise at least one selected from the group consisting of benzyldimethylamine, N,N-dimethylcyclohexylamine, and triethylamine.

The reaction rate controlling agent may be employed in an amount of 0.05 part by weight to 2 parts by weight relative to 100 parts by weight of the urethane-based prepolymer. Specifically, the reaction rate controlling agent may be employed in an amount of 0.05 part by weight to 1.8 parts by weight, 0.05 part by weight to 1.7 parts by weight, 0.05 part by weight to 1.6 parts by weight, 0.1 part by weight to 1.5 parts by weight, 0.1 part by weight to 0.3 part by weight, 0.2 part by weight to 1.8 parts by weight, 0.2 part by weight to 1.7 parts by weight, 0.2 part by weight to 1.6 parts by weight, 0.2 part by weight to 1.5 parts by weight, or 0.5 part by weight to 1 part by weight, relative to 100 parts by weight of the urethane-based prepolymer. If the reaction rate controlling agent is used in the above content range, the curing reaction rate of the prepolymer composition may be appropriately controlled to form a polishing layer having pores of a desired size and hardness.

### Support Layer

According to an embodiment of the present invention, the polishing pad may comprise a support layer.

The support layer constitutes a sub pad and serves to support the polishing layer and to absorb and disperse an impact applied to the polishing layer. Thus, it minimizes damage and defects to the object to be polished during the polishing process using the polishing pad.

The support layer may comprise a nonwoven fabric or a suede, but it is not limited thereto.

In an embodiment, the support layer may be a resin-impregnated nonwoven fabric. The nonwoven fabric may be a fibrous nonwoven fabric comprising at least one selected from the group consisting of a polyester fiber, a polyamide fiber, a polypropylene fiber, and a polyethylene fiber.

The resin impregnated in the nonwoven fabric may comprise at least one selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, and a polyamide-based elastomer resin.

The support layer may have a thickness of, for example, 0.3 mm or more or 0.5 mm or more, and 3 mm or less, 2 mm or less, or 1 mm or less. As a specific example, the thickness of the support layer may be 0.3 mm to 3 mm or 0.5 mm to 1 mm.

The support layer may have a hardness of, for example, 50 Asker C or more, 60 Asker C or more, or 70 Asker C or more, and 100 Asker C or less, 90 Asker C or less, or 80 Asker C or less. As a specific example, the hardness of the support layer may be 50 Asker C to 100 Asker C or 60 Asker C to 90 Asker C.

In addition, an adhesive layer may be interposed between the polishing layer (top pad) and the support layer (sub pad).

The adhesive layer may comprise a hot melt adhesive. The hot melt adhesive may comprise at least one selected from the group consisting of a polyurethane resin, a polyester resin, an ethylene-vinyl acetate resin, a polyamide resin, and a polyolefin resin. Specifically, the hot melt adhesive may be at least one selected from the group consisting of a polyurethane resin and a polyester resin.

In addition, a double-sided adhesive tape may be laminated under the support layer. When it is applied to CMP equipment, it is attached to the platen for use once the release paper of the double-sided adhesive tape has been removed.

### Process for Preparing a Polishing Pad

The process for preparing a polishing pad according to an embodiment comprises preparing a composition for a polishing pad comprising a urethane-based prepolymer, a foaming agent, and a curing agent; injecting the composition for a polishing pad into a mold and curing it to prepare a polishing layer; and laminating the polishing layer with a support layer.

The specific types and contents of the urethane-based prepolymer, curing agent, and foaming agent are as exemplified above.

As a specific example, the foaming agent comprises a solid phase foaming agent, the solid phase foaming agent comprises at least one selected from the group consisting of an acrylonitrile-based copolymer, a methyl methacrylate-based copolymer, a methacrylonitrile-based copolymer, and an acrylic-based copolymer, and the curing agent comprises at least one selected from the group consisting of diethyltoluenediamine (DETDA), 3,5-dimethylthio-2,6-diaminotoluene (DMTDA), 1,3-propanediol bis(4-aminobenzoate) (PDPAB), N,N′-bis(sec-butylamino)diphenylmethane, 2,6-bis(methylthio)-4-methyl-1,3-benzenediamine, 4-(4-aminobenzoyl)oxyphenyl 4-aminobenzoate, 4-(4-aminobenzoyl)oxybutyl 4-aminobenzoate, 4-[4-(4-aminobenzoyl)oxy-3-methylbutoxy]butyl 4-aminobenzoate, and methylene bis-methylanthranilate (MBNA).

The composition for a polishing pad may be prepared by sequentially or simultaneously mixing a urethane-based prepolymer, a foaming agent, and a curing agent.

As an example, the step of preparing the composition for a polishing pad may be carried out by mixing a urethane-based prepolymer with a curing agent, followed by further mixing with a foaming agent, or by mixing the urethane-based prepolymer with the foaming agent, followed by further mixing with the curing agent.

As another example, a urethane-based prepolymer, a curing agent, and a foaming agent may be put into the mixing process substantially at the same time. If a foaming agent, a surfactant, and an inert gas are further added, they may be put into the mixing process substantially at the same time.

As another example, a urethane-based prepolymer, a foaming agent, and a surfactant may be mixed in advance, and a curing agent, or a curing agent with an inert gas, may be subsequently added.

The mixing initiates the reaction of the urethane-based prepolymer and the curing agents and uniformly disperses the foaming agent and the inert gas in the raw materials. In such an event, a reaction rate controlling agent may intervene in the reaction between the urethane-based prepolymer and the curing agent from the beginning of the reaction, to thereby control the reaction rate. Specifically, the mixing may be carried out at a speed of 1,000 rpm to 10,000 rpm or 4,000 rpm to 7,000 rpm. Within the above speed range, it may be more advantageous for the inert gas and the foaming agent to be uniformly dispersed in the raw materials.

In addition, the step of preparing the composition for a polishing pad may be carried out under the condition of 50° C. to 150° C. If necessary, it may be carried out under vacuum defoaming conditions.

If the foaming agent comprises a solid phase foaming agent, the step of preparing the composition for a polishing pad may comprise mixing the urethane-based prepolymer and the solid phase foaming agent to prepare a first preliminary composition; and mixing the first preliminary composition and the curing agent to prepare a second preliminary composition.

The first preliminary composition may have a viscosity at about 80° C. of about 1,000 cps to about 2,000 cps, about 1,000 cps to about 1,800 cps, about 1,000 cps to about 1,600 cps, or about 1,000 cps to about 1,500 cps.

If the foaming agent comprises a gas phase foaming agent, the step of preparing the composition for a polishing pad may comprise preparing a third preliminary composition comprising the urethane-based prepolymer and the curing agent; and feeding the gas phase foaming agent to the third preliminary composition to prepare a fourth preliminary composition. In an embodiment, the third preliminary composition may further comprise a solid phase foaming agent.

According to an embodiment, the step of preparing a polishing layer comprises preparing a mold preheated to a first temperature; and injecting the composition for a polishing pad into the preheated mold and curing it; and post-curing the cured composition for a polishing pad under a second temperature condition higher than the preheating temperature.

According to an embodiment, the temperature difference between the first temperature and the second temperature may be about 10° C. to about 40° C., for example, about 10° C. to about 35° C. or about 15° C. to about 35° C. As a specific example, the first temperature may be about 60° C. to about 100° C., about 65° C. to about 95° C., or about 70° C. to about 90° C. As a specific example, the second temperature may be about 100° C. to about 130° C., for example, about 100° C. to about 125° C. or about 100° C. to about 120° C.

The step of curing the composition for a polishing pad at the first temperature may be carried out for about 5 minutes to about 60 minutes, about 5 minutes to about 40 minutes, about 5 minutes to about 30 minutes, or about 5 minutes to about 25 minutes.

The step of post-curing the composition for a polishing pad cured at the first temperature at the second temperature may be carried out for about 5 hours to about 30 hours, about 5 hours to about 25 hours, about 10 hours to about 30 hours, about 10 hours to about 25 hours, about 12 hours to about 24 hours, or about 15 hours to about 24 hours.

Thereafter, the step of injecting the composition for a polishing pad into a mold and curing it may be carried out under the temperature condition of 60° C. to 120° C. and the pressure condition of 50 kg/m² to 200 kg/m².

In addition, the above preparation process may further comprise the steps of cutting the surface of a polishing pad thus obtained, machining grooves on the surface thereof, bonding it with a lower part, inspection, packaging, and the like. These steps may be carried out in a conventional manner for preparing a polishing pad.

As an example, the process for preparing a polishing pad may further comprise machining at least one side of the polishing layer. The step of machining at least one side of the polishing layer may comprise forming grooves on at least one side of the polishing layer; line turning at least one side of the polishing layer; and roughening at least one side of the polishing layer.

The grooves may comprise at least one of concentric circular grooves spaced apart from the center of the polishing layer at a certain interval; and radial grooves continuously connected from the center of the polishing layer to the edge of the polishing layer. The line turning may be carried out by cutting the polishing layer to a certain thickness using a cutting tool. The roughening may be carried out by machining the surface of the polishing layer with a sanding roller.

### Process for Preparing a Semiconductor Device

The process for preparing a semiconductor device according to another embodiment comprises polishing the surface of a semiconductor substrate using the polishing pad.

Specifically, the process for preparing a semiconductor device may comprise providing the polishing pad according to an embodiment; and relatively rotating the polishing surface of the polishing layer and the surface of a semiconductor substrate while they are in contact with each other to polish the surface of the semiconductor substrate.

FIG. 2 illustrates a process for preparing a semiconductor device using a polishing pad according to an embodiment. Referring to FIG. 2, once the polishing pad (100) according to an embodiment has been attached to a platen (200), a semiconductor substrate (600) as an object to be polished is disposed on the polishing pad (100). In such an event, the surface of the semiconductor substrate (600) to be polished is in direct contact with the polishing surface of the polishing pad (100). A polishing slurry (400) may be sprayed through a nozzle onto the polishing pad for polishing. The flow rate of the polishing slurry (400) supplied through the nozzle may be selected according to the purpose within a range of about 10 cm³/minute to about 1,000 cm³/minute. For example, it may be about 50 cm³/minute to about 500 cm³/minute, but it is not limited thereto.

Thereafter, the semiconductor substrate (600) and the polishing pad (100) rotate relatively to each other, so that the surface of the semiconductor substrate (600) is polished. In such an event, the rotation direction of the semiconductor substrate (600) and the rotation direction of the polishing pad (100) may be the same direction or opposite directions. The rotation speeds of the semiconductor substrate (600) and the polishing pad (100) may each be selected according to the purpose within a range of about 10 rpm to about 500 rpm. For example, it may be about 30 rpm to about 200 rpm, but it is not limited thereto.

The semiconductor substrate (600) mounted on the polishing head (510) is pressed against the polishing surface of the polishing pad (100) at a predetermined load to be in contact therewith, and the surface thereof may then be polished. The load applied to the polishing surface of the polishing pad (100) through the surface of the semiconductor substrate (600) by the polishing head (510) may be selected according to the purpose within a range of about 1 gf/cm² to about 1,000 gf/cm². For example, it may be about 10 gf/cm² to about 800 gf/cm², but it is not limited thereto.

In an embodiment, the semiconductor substrate (600) as an object to be polished may comprise an oxide layer, a tungsten layer, or a composite layer thereof. Specifically, the semiconductor substrate (600) may comprise an oxide layer, a tungsten layer, or a composite layer of an oxide layer and a tungsten layer. The composite layer of an oxide layer and a tungsten layer may be a multilayer film in which the tungsten layer is laminated on one side of the oxide layer or may be a single-layer film in which an oxide region and a tungsten region are mixed in a single layer. As the object to be polished has such a film substance, and, at the same time, the polishing pad has characteristics according to the embodiment, a semiconductor device fabricated according to the process for preparing a semiconductor device may have minimum defects.

In an embodiment, the process for preparing a semiconductor device may further comprise, in the step of polishing the object to be polished, supplying any one of a slurry for polishing an oxide layer and a slurry for polishing a tungsten layer; or sequentially supplying the slurry for polishing an oxide layer and the slurry for polishing a tungsten layer to the polishing surface.

For example, if the semiconductor substrate as an object to be polished comprises an oxide layer, the process for preparing a semiconductor device may comprise supplying a slurry for polishing an oxide layer. If the semiconductor substrate comprises a tungsten layer, the process for preparing a semiconductor device may comprise supplying a slurry for polishing a tungsten layer. If the semiconductor substrate comprises a composite layer of an oxide layer and a tungsten layer, the process for preparing a semiconductor device may comprise sequentially supplying a slurry for polishing an oxide layer and a slurry for polishing a tungsten layer to the polishing surface. Here, depending on the process, the slurry for polishing an oxide layer may be supplied first and then the slurry for polishing a tungsten layer may be supplied later, or the slurry for polishing a tungsten layer may be supplied first and then the slurry for polishing an oxide layer may be supplied later.

In an embodiment, in order to maintain the polishing surface of the polishing pad (100) in a state suitable for polishing, the process for preparing a semiconductor device may further comprise processing the polishing surface of the polishing pad (100) with a conditioner (470) simultaneously with polishing the semiconductor substrate (600).

As the polishing pad according to an embodiment has a content of chlorine in the polishing layer adjusted to a certain range, it is possible to reduce the size of debris while maintaining excellent physical properties and performance of the polishing pad, thereby minimizing the occurrence of defects and scratches during a CMP process. Thus, it is possible to efficiently prepare a semiconductor device with high quality using the polishing pad

### MODE FOR THE INVENTION

Hereinafter, the present invention is explained in detail by Examples. The following Examples are intended to further illustrate the present invention, and the scope of the Examples is not limited thereto.

### Preparation of a Polishing Pad

### Example 1

### (1) Preparation of a Urethane-Based Prepolymer

A four-necked flask was charged with toluene diisocyanate (TDI), dicyclohexylmethane diisocyanate (H12MDI), polytetramethylene ether glycol (PTMEG), and diethylene glycol (DEG), followed by reaction thereof at 80° C. for 3 hours, thereby preparing a urethane-based prepolymer having a content of NCO end groups (NCO %) of 10% by weight.

### (2) Preparation of a Polishing Pad

A casting machine equipped with tanks and feeding lines for the raw materials such as the urethane-based prepolymer, a curing agent, an inert gas, and a foaming agent was provided. The urethane-based prepolymer prepared above, a curing agent (4,4′-methylenebis(2-chloroaniline), MOCA), a solid phase foaming agent (acrylonitrile/dichloroethane, expanded cell type, average particle size: 40 μm to 42 μm), an inert gas (N₂), and a silicone-based surfactant (Manufacturer: Evonik) were each charged to the tanks. Here, the solid phase foaming agent was fed at 1.5 parts by weight relative to 100 parts by weight of the urethane-based prepolymer, and the urethane-based prepolymer and the curing agent were fed at an equivalent ratio of 1:1 and a total amount of 10 kg/minute.

Thereafter, the raw materials were stirred while they were fed to the mixing head at constant rates through the respective feeding lines (mixing head rotation speed:approximately 5,000 rpm). A mold (1,000 mm×1,000 mm×3 mm) was prepared and preheated at a temperature of 80° C. The stirred mixture was injected into the mold and reacted to obtain a molded article in the form of a solid cake. Thereafter, the top and bottom of the molded article were each ground to obtain a polishing layer for a top pad.

Thereafter, the polishing layer was subjected to surface milling and groove-forming steps and laminated with a support layer for a sub pad by a hot melt adhesive, thereby preparing a polishing pad. In such an event, a double-sided adhesive tape (model name: 442JS, manufacturer: 3M) was laminated under the support layer so that it could be attached to the platen of CMP equipment.

### Example 2

A polishing pad was prepared in the same manner as in Example 1, except that, in step (2), a solid phase foaming agent (acrylonitrile/methacrylonitrile copolymer, expanded cell type, average particle size: 40 μm to 42 μm) was used.

### Example 3

A polishing pad was prepared in the same manner as in Example 1, except that, in step (2), the equivalent ratio of the urethane-based prepolymer and the curing agent was 1:0.8.

### Comparative Example 1

A commercially available polishing pad (model name: IK4140, manufacturer: Dupont) was used as Comparative Example 1.

### Comparative Example 2

A commercially available polishing pad (model name: IC1010, manufacturer: Dupont) was used as Comparative Example 2.

### Test Example 1: Sound Absorption Coefficient and Damping Ratio

The polishing pads of Examples 1 to 3 and Comparative Examples 1 and 2 were each measured for a sound absorption coefficient and a damping ratio according to KS F 2814-2.

Specifically, according to KS F 2814-2, the polishing pad was cut, the specimen was placed within an impedance tube, and a plane wave sound source was generated within the pipe to measure sound pressure. In addition, the maximum sound absorption coefficient was calculated according to the following Equation 1. In such an event, the running frequency range was 500 Hz to 4,000 Hz.

$$Sound absorption coefficient = ( {I}_{i} - {I}_{r} ) / {I}_{i} = ( {I}_{a} + {I}_{t} ) / {I}_{i} \qquad [ Equation 1 ]$$

In Equation 1, when the polishing pad is cut (diameter: 45 mm) to measure sound pressure within an impedance tube according to KS F 2814-2, Iᵢ is the intensity of the incident sound, Iᵣ is the intensity of the reflected sound, Iₐ is the intensity of the absorbed sound, and Iₜ is the intensity of the transmitted sound.

### Test Example 2: Polishing Rate (Removal Rate)

The polishing pads of Examples 1 to 3 and Comparative Examples 1 and 2 were each fixed to the platen of CMP equipment, and a silicon wafer (diameter 300 mm) was set with the silicon oxide layer thereof facing downward. Then, a CMP process was carried out to measure the polishing rate.

Specifically, the silicon oxide layer was polished under a polishing load of 4.0 psi while the platen was rotated at a speed of 150 rpm for 60 seconds and a calcined ceria slurry or a calcined silica slurry was supplied onto the polishing pad at a rate of 250 ml/minute. Upon completion of the polishing, the silicon wafer was detached from the carrier, mounted in a spin dryer, washed with deionized water, and then dried for 15 seconds with nitrogen. The difference in the thickness of the silicon oxide layer in the dried silicon wafer before and after the polishing was measured using a spectral reflectometer-type thickness measuring instrument (model: SI—F80R, manufacturer: Keyence). The polishing rate was calculated according to the following Mathematical Equation 1.

$$Polishing rate ( Å / minute ) = \qquad [ Mathematical Equation 1 ]$$

$$difference in thickness before and after polishing ( Å ) /$$

$$polishing time ( minute )$$

### Test Example 3: Defects

The polishing pads of Examples 1 to 3 and Comparative Examples 1 and 2 were each measured for changes in defects before and after polishing.

Specifically, polishing was carried out in the same manner as in Test Example 2 using a CMP polishing machine. Upon completion of the polishing, the silicon wafer was transferred to a cleaner and cleaned for 10 seconds each using 1% HF, deionized water (DIW), and 1% H₂NO₃. Thereafter, it was transferred to a spin dryer, washed with deionized water (DIW), and then dried with nitrogen for 15 seconds. The change in defects of the dried silicon wafer before and after the polishing was measured using a defect measurement device (manufacturer: Tenkor, model: XP+). Specifically, the total number of scratches, chatter marks, pits, and residues on the surface of the wafer was measured.

TABLE 1

| | Sound | | | |
|---|---|---|---|---|
| | absorption | Polishing rate (Å/min) | | Defect/scratch |
| | coefficient | Silica slurry | Ceria slurry | (count) |
| Ex. 1 | 0.200 | 2,295.0 | 3,906.9 | 7 |
| Ex. 2 | 0.121 | 2,317.8 | 3,938.7 | 9 |
| Ex. 3 | 0.102 | 2,220.7 | 3,908.7 | 9 |
| C. Ex. 1 | 0.088 | 2,109.0 | 3,800.4 | 13 |
| C. Ex. 2 | 0.099 | 2,093.7 | 3,484.7 | 12 |

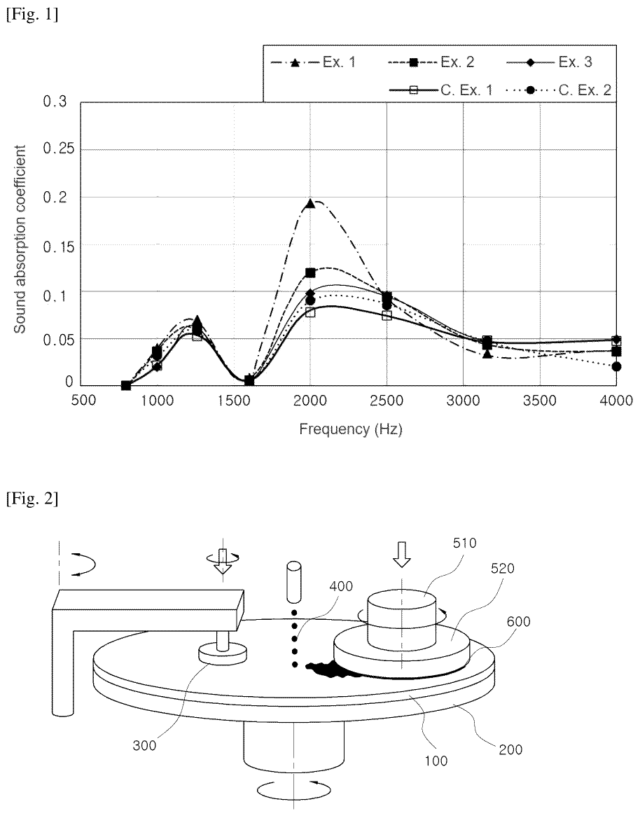

As can be seen from Table 1 above, the polishing pads of Examples 1 to 3 had excellent sound absorption characteristics, significantly fewer defects and scratches, and excellent polishing rates. Specifically, the polishing pads of Examples 1 to 3 had a maximum sound absorption coefficient of 0.1 or more in the frequency range of 500 Hz to 4,000 Hz, indicating that their sound absorption characteristics were very excellent as compared with the conventional polishing pads of Comparative Examples 1 and 2 (see FIG. 1). In addition, the polishing pads of Examples 1 to 3 had a maximum sound absorption coefficient of 0.1 or more in the frequency range of 500 Hz to 4,000 Hz; thus, they could minimize energy loss caused by heat energy or vibration energy in the CMP polishing process, resulting in an excellent polishing rate as compared with Comparative Examples 1 and 2. They also had significantly fewer defects and scratches.

1. A polishing pad, which comprises a polishing layer, wherein the polishing layer comprises a urethane-based prepolymer, a foaming agent, and a curing agent, and the maximum sound absorption coefficient is 0.1 or more as measured at a frequency of 500 Hz to 4,000 Hz according to the following Equation 1:
$$Sound absorption coefficient = ( {I}_{i} - {I}_{r} ) / {I}_{i} = ( {I}_{a} + {I}_{t} ) / {I}_{i} \qquad [ Equation 1 ]$$
in Equation 1, when the polishing pad is cut (diameter: 45 mm) to measure sound pressure within an impedance tube according to KS F 2814-2, Iᵢ is the intensity of the incident sound, Iᵣ is the intensity of the reflected sound, Iₐ is the intensity of the absorbed sound, and Iₜ is the intensity of the transmitted sound.

2. The polishing pad of claim 1, wherein the maximum sound absorption coefficient is 0.05 or more as measured at a frequency of 1,000 Hz to 1,500 Hz, and the maximum sound absorption coefficient is 0.1 or more as measured at a frequency of 1,500 Hz to 3,000 Hz.

3. The polishing pad of claim 1, wherein the foaming agent comprises at least one selected from a solid phase foaming agent comprising particles having a hollow structure, a liquid phase foaming agent using a volatile liquid, and an inert gas.

4. The polishing pad of claim 1, wherein the foaming agent comprises a solid phase foaming agent, and the solid phase foaming agent comprises at least one selected from the group consisting of an acrylonitrile-based copolymer, a methyl methacrylate-based copolymer, a methacrylonitrile-based copolymer, and an acrylic-based copolymer.

5. The polishing pad of claim 4, wherein the solid phase foaming agent has an average particle size of 5 μm to 100 μm, and the content thereof is 0.1 part by weight to 5 parts by weight relative to 100 parts by weight of the urethane-based prepolymer.

6. The polishing pad of claim 1, wherein the curing agent comprises at least one selected from the group consisting of 4,4′-methylenebis(2-chloroaniline) (MOCA), diethyltoluenediamine (DETDA), 3,5-dimethylthio-2,6-diaminotoluene (DMTDA), 1,3-propanediol bis(4-aminobenzoate) (PDPAB), N,N′-bis(sec-butylamino)diphenylmethane, 2,6-bis(methylthio)-4-methyl-1,3-benzenediamine, 4-(4-aminobenzoyl)oxyphenyl 4-aminobenzoate, 4-(4-aminobenzoyl)oxybutyl 4-aminobenzoate, 4-[4-(4-aminobenzoyl)oxy-3-methylbutoxy]butyl 4-aminobenzoate, and methylene bis-methylanthranilate (MBNA).

7. The polishing pad of claim 1, wherein the content of the curing agent is 5 parts by weight to 50 parts by weight relative to 100 parts by weight of the urethane-based prepolymer.

8. The polishing pad of claim 1, wherein the equivalent ratio of the urethane-based prepolymer and the curing agent is 1:0.5 to 2.

9. The polishing pad of claim 1, wherein the urethane-based prepolymer is prepared by reacting an isocyanate compound and a polyol.

10. The polishing pad of claim 9, wherein the isocyanate compound comprises one selected from the group consisting of toluene 2,4-diisocyanate (2,4-TDI), toluene 2,6-diisocyanate (2,6-TDI), naphthalene 1,5-diisocyanate, para-phenylene diisocyanate, tolidine diisocyanate, 4,4′-diphenylmethane diisocyanate, hexamethylene diisocyanate, dicyclohexylmethane diisocyanate, isophorone diisocyanate, and combinations thereof.

11. The polishing pad of claim 9, wherein the polyol comprises one selected from the group consisting of polytetramethylene ether glycol, polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol, dipropylene glycol, tripropylene glycol, and combinations thereof.

12. The polishing pad of claim 9, wherein the polyol has a weight average molecular weight (Mw) of 100 g/mole to 3,000 g/mole.

13. The polishing pad of claim 1, wherein the urethane-based prepolymer has a weight average molecular weight (Mw) of 500 g/mole to 3,000 g/mole.

14. The polishing pad of claim 1, wherein the urethane-based prepolymer has an isocyanate end group content (NCO %) of 8% by weight to 11% by weight.

15. The polishing pad of claim 1, wherein the polishing layer has a hardness of 50 Shore D to 65 Shore D, a tensile strength of 15 N/mm² to 25 N/mm², and an elongation of 90% to 130%.

16. The polishing pad of claim 1, wherein the polishing layer has a thickness of 0.8 mm to 5 mm and a specific gravity of 0.6 g/cm³ to 0.9 g/cm³.

17. The polishing pad of claim 1, wherein the polishing layer comprises a plurality of pores formed from the foaming agent, the average diameter of the pores is 10 μm to 60 μm, and the total area of the pores is 30% to 60% based on the total area of the polishing layer.

18. The polishing pad of claim 1, wherein, when the silicon oxide layer of a silicon wafer is polished with a ceria slurry using the polishing pad, the polishing rate according to the following Mathematical Equation 1 is 2,150 Å/minute to 3,500 Å/minute:
Polishing rate (Å/minute)=difference in thickness before and after polishing (Å)/polishing time (minute). [Mathematical Equation 1]

19. The polishing pad of claim 1, wherein, when the silicon oxide layer of a silicon wafer is polished with a silica slurry using the polishing pad, the average polishing rate according to the following Mathematical Equation 1 is 3,500 Å/minute to 4,500 Å/minute:
$$Polishing rate ( Å / minute ) = \qquad [ Mathematical Equation 1 ]$$
$$difference in thickness before and after polishing ( Å ) /$$
$$polishing time ( minute ) .$$

20. A process for preparing a semiconductor device, which comprises polishing the surface of a semiconductor substrate using the polishing pad of claim 1.
